(19) United States
(12) Patent Application Publication
(10) Pub. No.: US 2026/0313784 A1
(43) Pub. Date: Oct. 8, 2026

(54) STEPPED TRACE DESIGN FOR IMPEDANCE COMPENSATION OF HIGH-SPEED DIFFERENTIAL PAIR CHANNELS

(71) Applicant: Advanced Micro Devices, Inc., Santa Clara, CA (US)

(72) Inventor: Mohd Muhaiyiddin BIN ABDULLAH, Penang (MY)

(21) Appl. No.: 19/172,424

(22) Filed: Apr. 7, 2025

(51) Int. Cl. H05K 1/02; H01L 23/538; H01L 25/065

(52) U.S. Cl. CPC H05K 1/0245; H05K 1/024; H05K 1/025; H10W 70/611; H10W 70/635; H10W 70/65; H10W 90/00; H05K 2201/0187; H05K 2201/09227; H05K 2201/10325; H05K 2201/10378; H05K 2201/10522; H05K 2201/10704; H05K 2201/10719; H05K 2201/10734

(57) ABSTRACT

Adjusting the impedance of printed circuit board (PCB) differential signal trace pairs in an integrated circuit socket break-out region to substantially match the impedance of differential signal trace pairs in a main-route region is accomplished by increasing the thickness of the differential signal trace pairs in the break-out region. This allows maintaining the required width and spacing of the differential signal trace pairs in the x and y directions of the break-out region, and adding copper thickness in the z direction to reduce the impedance of the differential signal trace pairs to the impedance of the differential signal trace pairs in the main-route region. This impedance matching minimizes signal reflection losses, distortion and standing waves. Increasing the relative dielectric constant εᵣ of the PCB in the break-out region may also be used to adjust the impedance of the differential signal trace pairs therein. Substitute substrate of SiP instead of PCB.

### TECHNICAL FIELD

Embodiments of the present disclosure generally relate to impedance compensation of high-speed differential pair channels, and in particular, to using stepped height traces for impedance compensation of the high-speed differential pair channels.

### BACKGROUND

A large-scale integrated circuit (IC) package may be connected to a printed circuit board using land grid array (LGA), pin grid array (PGA) or ball grid array (BGA) connections on the IC package. LGA packaging is related to BGA and PGA packaging. Unlike pin grid array (PGA), land grid array (LGA) packages are designed to fit either in a socket, or be soldered to a PCB using surface mount technology. BGA packages, however, have solder balls as their contacts in-between the IC package and the PCB contact traces. The solder balls are normally attached to the underside of the IC package. PGA packages cannot be soldered to a PCB using surface mount technology and have to be connected to the PCB with a socket that is adapted to receive the pins of the PGA. In contrast with BGA, land grid array (LGA) packages in non-socketed configurations have no solder balls, and use flat contacts (traces) adapted to contact the PCB contacts.

High speed data signals may be transmitted and received on high-speed differential pair channels. The differential pair channels act as fixed impedance transmission lines to minimize signal reflections and distortions caused by mismatched impedances between sections of the transmission lines. An impedance of a differential pair channel is determined by the widths and thicknesses of the transmission line conductors, spacing between the two conductors (traces) of each differential pair channel, and substrate dielectric constant.

Typically, a nominal 85-ohm impedance may be selected for main differential pair traces when using typical industry high volume manufacturing (HVM) capabilities. However, the high density and close spacings of the newer LGA, PGA and BGA packaging technologies do not allow for sufficient areas to achieve the nominal 85-ohm impedance desired. Thus, the “break-out differential pair traces” running underneath and between the PCB traces or IC socket pins have impedances that may be higher than the desired nominal 85-ohm impedance of the main-route differential pair traces on the PCB. The “break-out differential pair traces” may have an impedance, for example, 15 ohms higher than the desired nominal 85-ohm impedance. This 15-ohm impedance difference causes an eight percent reflection loss to the data signals from one break-out section transition alone. Data transmission rates in the hundreds of gigabits per second range and multi-character modulation such as pulse amplitude modulation (PAM) are very sensitive to voltage noise such as crosstalk, power noise as well as standing wave reflections that will degrade data transmission performance (higher bit error rates).

What is needed is a way to better control impedance of the break-out differential pair traces to be closer to the target impedance (85 ohms) of the main-route differential pair traces to minimize signal reflection losses and use existing manufacturing capabilities.

### SUMMARY

In one example of the disclosure, a printed circuit board (PCB) includes a plurality of first trace pairs in a break-out region of a printed circuit board (PCB). A plurality of second trace pairs in a main-route region of the PCB, wherein the plurality of first trace pairs have impedances substantially the same as the impedances of the second trace pairs. First ends of the plurality of the first trace pairs are for coupling to connections of an integrated circuit socket. Second ends of the plurality of the first trace pairs are coupled to first ends of the plurality of second trace pairs.

In one example of the disclosure, a method for impedance compensation of high-speed printed circuit board (PCB) differential pair channels includes providing a plurality of first trace pairs in a break-out region of a printed circuit board (PCB), wherein the plurality of first trace pairs have a first impedance. Providing a plurality of second trace pairs in a main-route region of the PCB), wherein the plurality of second trace pairs have substantially the first impedance. Coupling first ends of the plurality of the first trace pairs to connections of an integrated circuit socket. Coupling second ends of the plurality of the first trace pairs to first ends of the plurality of second trace pairs.

In one example of the disclosure, a system in a package (SiP) includes a substrate. A plurality of first trace pairs in at least one break-out region of the substrate. A plurality of second trace pairs in a main-route region of the substrate, wherein the plurality of first trace pairs have impedances substantially the same as the impedances of the second trace pairs. At least one integrated circuit in the at least one break-out region of the substrate. First ends of the plurality of the first trace pairs are coupled to connections of the at least one integrated circuit. Second ends of the plurality of the first trace pairs are coupled to first ends of the plurality of second trace pairs.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIGS. 1A-1C illustrate representative schematic elevation and plan view diagrams of a land grid array (LGA) package, socket and printed circuit board (PCB), according to an example.

FIG. 2 illustrates a representative plan view diagram of break-out and main-route trace layouts on a PCB for an (LGA) package, according to an example.

FIG. 3 illustrates an elevation view of a differential microstrip on a printed circuit board and calculations therefor.

FIGS. 4A-4C illustrate representative schematic plan and elevation view diagrams of break-out and main-route traces on a PCB, according to an example.

FIG. 5 illustrates representative bar graphs of trace differential pair impedances versus plating thicknesses, according to an example.

FIG. 6 illustrates a representative elevation view diagram of two PCBs, each having an LGA package, connected together through a cable, according to an example.

FIG. 7 illustrates a representative elevation view diagram of two LGA packages connected together on a PCB through constant impedance differential pair traces, according to an example.

FIG. 8 illustrates is a representative schematic plan view diagram and impedance versus time TDR graph of different break-out trace impedances, according to an example.

FIG. 9 illustrates is a representative schematic frequency domain response diagram showing crosstalk comparing baselines, according to an example.

FIGS. 10A and 10B illustrate representative schematic plan and elevation view diagrams of break-out and main-route traces in a system in a package (SiP), according to an example.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

Impedance control of the transition between break-out from the integrated circuit (IC) package/socket connection traces to the printed circuit board (PCB) differential transmission line traces used for transmission of data signals to be closer to the target impedance of the printed circuit board differential pair traces (transmission lines), according to the teaching of this disclosure is disclosed herein. When the signal transmission traces from the IC package/socket are close to the target impedance of the PCB differential transmission line traces, signal reflection losses are minimized. Enabling existing board manufacturing capabilities to achieve this is also of significant benefit.

The main-route land sections on the PCB may use industry standard common conductive trace thickness, width and spacing on standard PCB materials since there is more room to tune trace width and spacing to yield a target characteristic impedance and target loss signal. At the break-out section under the IC package connections, the metal layer of the traces under the IC package may be thicker than the metal layer of the traces after the break-out on the PCB, which provides for more capacitive coupling between the two traces of the transmission line (under the IC package) as well as to the adjacent trace layer to reduce impedance to the design target, e.g. 85-ohms. This results in a stepped height of the traces between the break-out and main-route sections, where the height of the break-out traces are greater than the height of the main-route traces. The capacitance of the break-out trace pairs is determined by the areas (e.g., length and height) of and distance between the two traces of the break-out trace pair. The larger the areas of the break-out trace pair, the larger the capacitance thereof. Alternatively, or in addition to larger break-out trace pair areas, the dielectric coefficient of the PCB material in the break-out area may be increased to increase the capacitance of the break-out trace pair. Increased height of the break-out trace pair will also decrease resistance thereof to make up for the thinner trace widths of the closer spaced break-out trace pair.

A system in a package (SiP) may also benefit from the teachings of this disclosure. A plurality of integrated circuit modules may be fabricated as a system in a package or system-in-package (SiP) where the SiP may comprise a power management module, a plurality of digital processors, a memory stack, and a communications module, etc. Modules of the SiP may comprise a plurality of integrated circuits, and active and passive devices (components, e.g., resistors, capacitors, inductors, diodes, etc.). These modules may be stacked, placed side-by-side and/or embedded into a substrate. The modules of the SiP may be connected together with copper lands (conductors), e.g., trace pairs, embedded in the SiP substrate, and/or a plurality of substrates, e.g., plurality of redistributed layers (RDL), that may be attached and electrically connected to an interposer substrate that may also have external connections, e.g., land grid array (LGA), pin grid array (PGA) or ball grid array (BGA) connections on the SiP for further connecting to an electronic system printed circuit board. One having ordinary skill in the art of integrated circuit manufacturing and the benefit of this disclosure could apply the break-out trace pair impedance lowering techniques described and claimed hereinafter to fabrication of SiP devices.

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

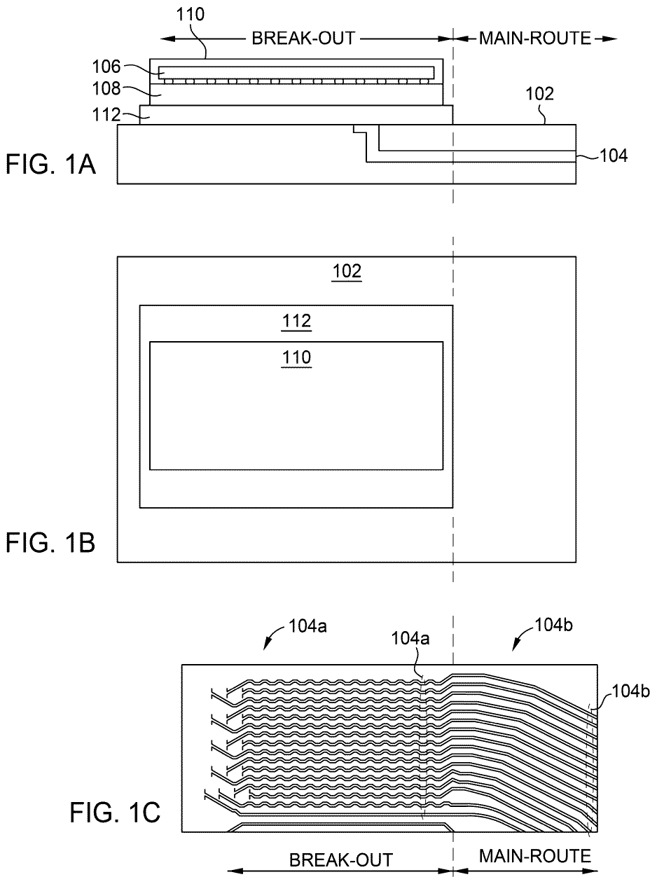

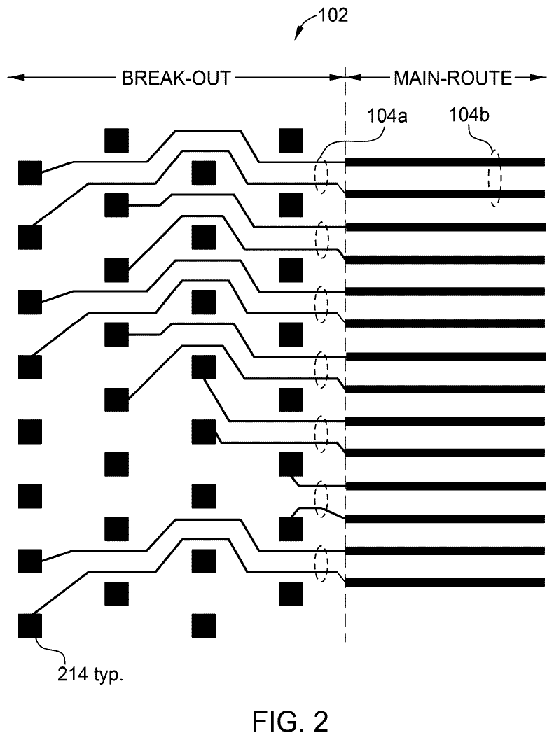

Referring to FIGS. 1A-1C, depicted are representative schematic elevation and plan view diagrams of a land grid array (LGA) package, socket and printed circuit board (PCB), according to an example. FIG. 1A illustrates an elevation view. FIG. 1B illustrates a plan view. A PCB 102 has conductive traces 104 embedded therein (i.e., multi-layer PCB) 102. An IC package socket 112 is mounted on the PCB 102 and electrically connected to the traces 104. An integrated circuit 106 may be connected to an interposer 108 and both are housed in an IC package 110. FIG. 1C illustrates a plan view of trace pairs 104a in a region under the IC package socket 112 and trace pairs 104b in a main-route region outside of the break-out region. The trace pairs 104a are thinner and closer together than the trace pairs 104b because of the reduced spacing between the connections 214 (FIG. 2) under the IC package socket 112. This would normally make the impedance of the break-out trace pairs 104a greater than the impedance of the main-route trace pairs 104b if all traces 104 were of the same height. However, what is disclosed and claimed hereinafter provides for a closer impedance match between the break-out trace pairs 104a and the main-route trace pairs 104b. Different portions of the trace pairs 104 may be in different layers of the multi-layer PCB 102 and connected together with vias.

Referring to FIG. 2, depicted is a representative plan view diagram of break-out and main-route trace layouts on a PCB for an (LGA) package, according to an example. The break-out trace pairs 104a have to be narrower and closer together to get around the IC package socket contacts 214 in the break-out area under the IC package socket 112. These limitations result in a higher impedance than desired. The main-route trace pairs 104b have more area available to optimize the design of the trace pairs 104b for a desired impedance, e.g., 85 ohms.

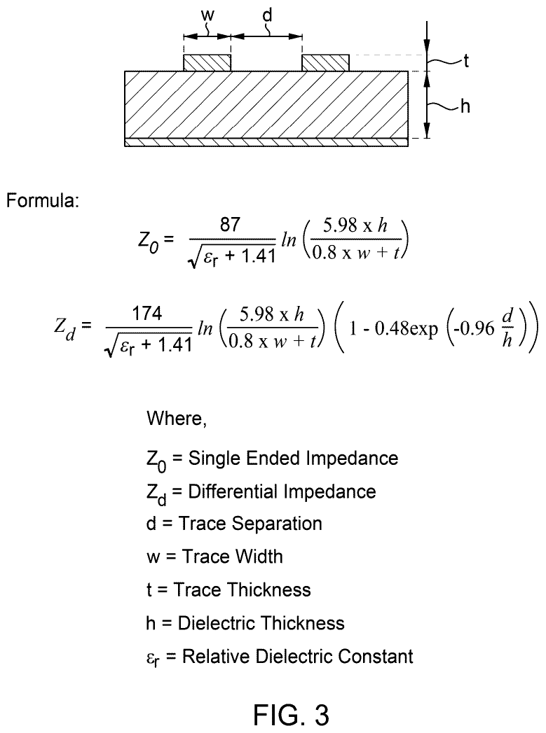

Referring to FIG. 3, depicted is an elevation view of a differential microstrip on a printed circuit board and calculations therefor. The impedance of a trace pair 104 depends upon the separation, d, between the traces; the widths, w, and thicknesses, t; and relative dielectric constant εᵣ. Any increase in the aforementioned characteristics will lower the impedance Zₒ and Z_{d}. Since width, w, and distance, d, are constrained in the break-out area, the only physical characteristics that realistically may be varied are the trace thickness, t, and the relative dielectric constant, εᵣ, of the PCB.

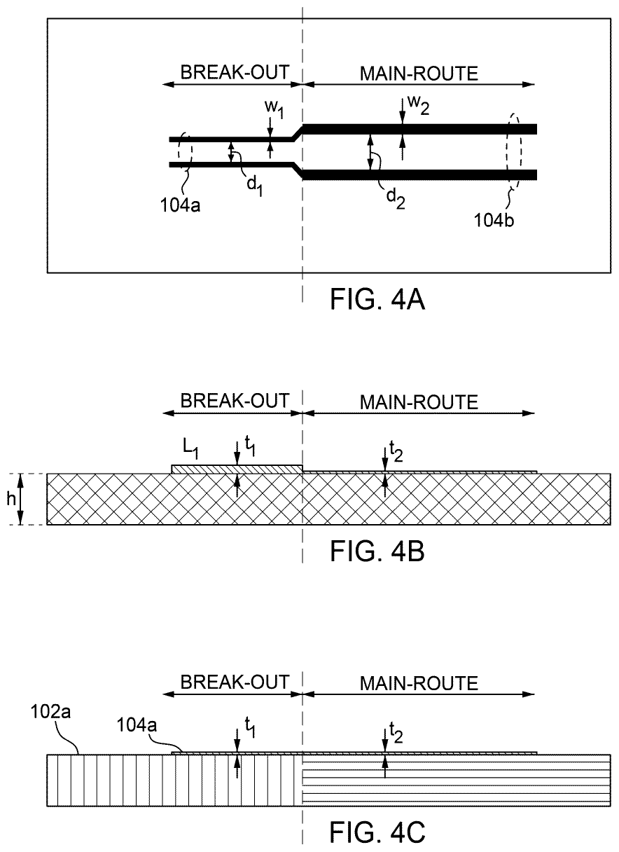

Referring to FIGS. 4A-4C, depicted are representative schematic plan and elevation view diagrams of break-out and main-route traces on a PCB, according to an example. FIG. 4A shows a plan view of a single trace pair 104 comprising a trace pair 104a portion in the break-out area under the IC package socket 112 and a trace pair 104b portion in the main-route area. The characteristics of the trace pair 104b may be easily manipulated to provide a desired impedance, e.g., 85 ohms, since there is enough room to do so. However, the break-out area under the IC package socket 112 is limited due to the close spacing of the IC package socket contacts 214 and trace 104 routing therethrough.

FIG. 4B shows an elevation view of the single trace pair 104 shown in FIG. 4A. A preferred way to decrease the impedance of the trace pair 104a portion in the break-out region is to increase the thickness, t₁, thereof. This increased trace thickness (z-height) at the break-out region (t₁> t₂) provides additional capacitive coupling between traces 104a and to an adjacent plane of the PCB. Higher (larger, thicker) t₁ will add more capacitive coupling, hence reducing the impedance, e.g., 85 ohms, closer to a nominal design target (as a function of t₁). This requires no changes to the main-route trace regions.

This stepped trace design may be achieved by several ways such as using selective copper plating, etching stepped from a thicker copper base such as 2-oz copper, or copper sputtering. Most economical and reliable implementations may be provided with existing PCB manufacturing technologies. This trace step process need only be done for the SERDES (Serializer/Deserializer) routing layers, normally four routing layers on a typical server platform.

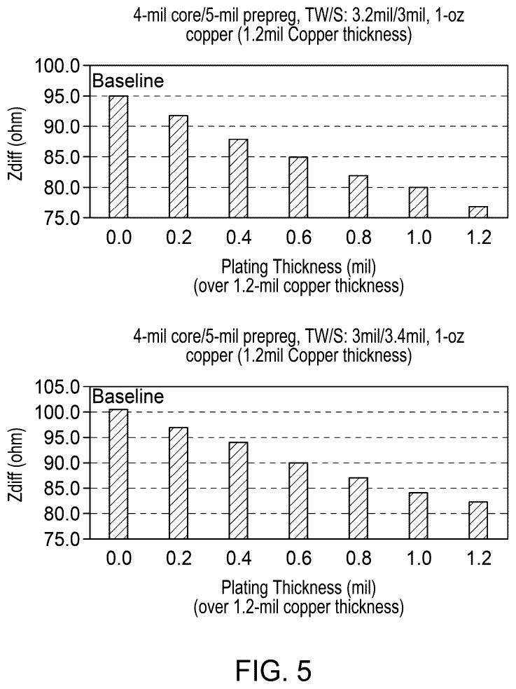

Referring to FIG. 5, depicted are representative bar graphs of trace differential pair impedances versus plating thicknesses, according to an example. The bar graphs of FIG. 5 show various combinations of copper plating thicknesses and resulting deferential impedances of the trace pair 104a.

Referring back to FIGS. 3 and 4C, using a higher relative dielectric constant εᵣ material in the makeup of the PCB 102a results in a higher dielectric constant (Dk) under the break-out region that decreases the impedance of the trace pair 104a. A combination of both an increase in the thickness, t₁, and an increase in the dielectric constant εᵣ material in the PCB portion 102a may be used to lower the impedance of the trace pair 104a. A higher relative dielectric constant εᵣ material may be used at any region of a PCB to help match impedances of trace pairs, and one having ordinary skill in the art of PCB manufacture and the benefit of this disclosure could apply such modifications.

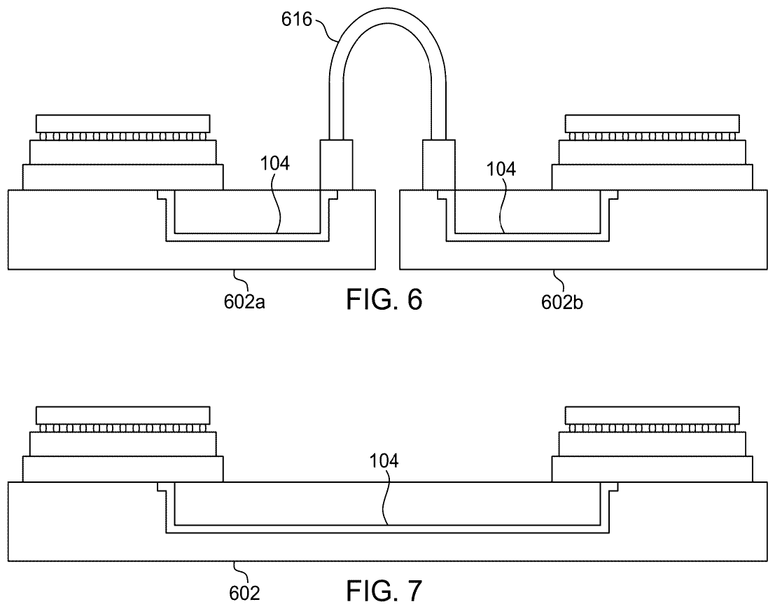

Referring to FIG. 6, depicted is a representative elevation diagram of two PCBs, each having an (LGA) package, connected together through a cable, according to an example. A pluggable cable 616 having a desired impedance, e.g., 85 ohms, may be used to interconnect two PCBs 602a and 602b. The impedance of trace pairs 104 will substantially match the impedance of the cable 616, according to the teachings of this disclosure.

Referring to FIG. 7, depicted is a representative elevation diagram of two (LGA) packages 110a and 110b connected together on a PCB through constant impedance differential pair traces 104, according to the teaching of this disclosure.

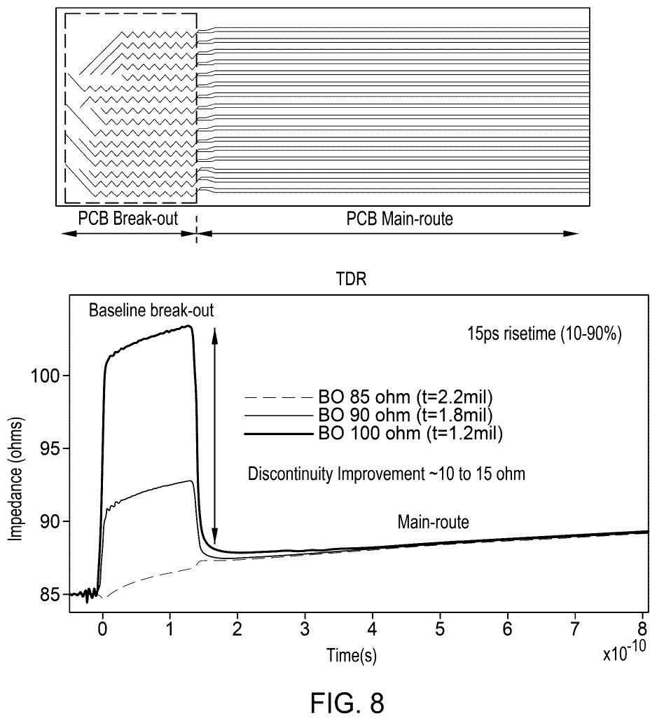

Referring to FIG. 8, depicted is a representative schematic plan view diagram and impedance versus time TDR graph of different break-out trace impedances, according to an example. The graph shown in FIG. 8 depicts the TDR (time domain reflectometry) pulse to impedance discontinuities of different impedances between the break-out trace pairs 104a and main-route trace pairs 104b. An additional break-out thickness of 0.6-mil will reduce the break-out trace pairs 104a impedance from 100-ohm to about 90-ohm. 1-mil additional thickness will bring impedance close to 85-ohm. Closer matching of the break-out impedance to the main-route impedance will result in an improvement of reflections losses of about 8 percent to less than 3 percent.

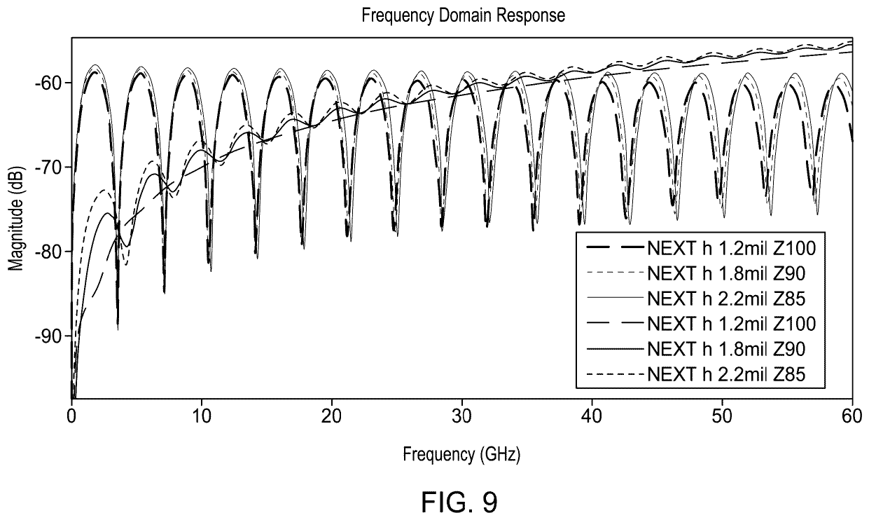

Referring to FIG. 9, depicted is a representative schematic frequency domain response diagram showing crosstalk comparing baselines, according to an example. The graphs of FIG. 9 depict “near-end crosstalk (NEXT) and “far-end crosstalk (FEXT). The NEXT graphs represent signal coupling or interference from one or multiple sources to another on the same end of the circuit. The FEXT graphs represent signal coupling or interference from one or multiple sources to another on the opposite end of the circuit. These plots show insignificant crosstalk differences between a baseline prior technology design and the proposed design using stepped height traces for impedance compensation of the high-speed differential pair channels, according to the teachings of this disclosure.

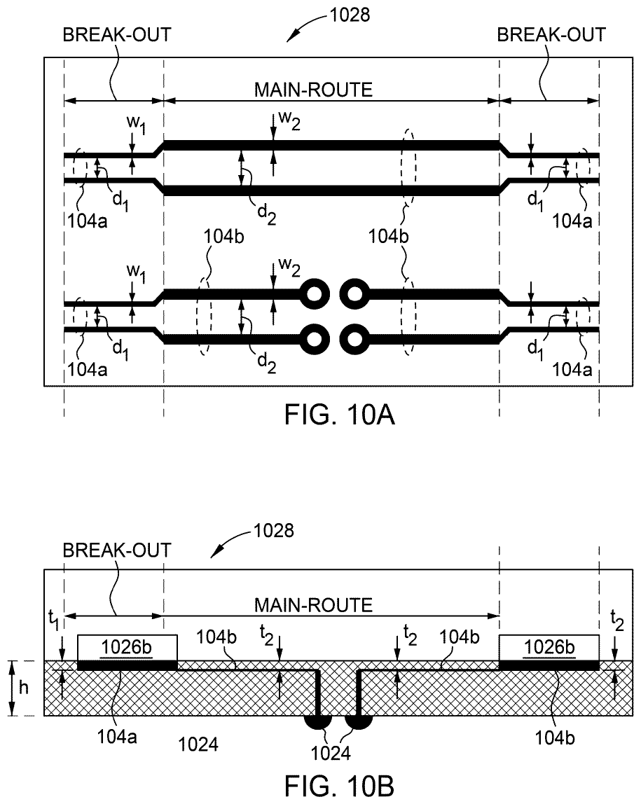

Referring to FIGS. 10A and 10B, depicted are representative schematic plan and elevation view diagrams of break-out and main-route traces in a “system in a package” (SiP), according to an example. A substrate 1022, such as at least one re-distribution layer (RDL), may have connection pads to at least one integrated circuit die 1026 that may be connected to a plurality of break-out trace pairs 104a embedded in the substrate 1022. The break-out trace pairs 104a are connected to respective ones of a plurality of main-route trace pairs 104b. The plurality of main-route trace pairs 104b may also be embedded in the substrate 1022. The thickness t₂ of the main-route trace pairs 104b may be formed in at least one RDL and the thickness t₁ of the break-out trace pairs 104a may be formed in a plurality of RDLs (stacked trace pairs). The stacked trace pairs may be connected together with vias or other means as necessary. The substrate 1022 may also include an interposer (not shown). External connections from the SiP 1028 may be made with vertical connections, e.g., through-silicon via (TSV) 1024. The TSVs 1024 may connect some of the main-route trace pairs 104b to external SiP connections 1024, e.g., C4 solder balls or pins.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed:

1. A printed circuit board (PCB), comprising:
a plurality of first trace pairs in a break-out region of a printed circuit board (PCB);
a plurality of second trace pairs in a main-route region of the PCB, wherein the plurality of first trace pairs have impedances substantially the same as the impedances of the second trace pairs;
first ends of the plurality of the first trace pairs for coupling to connections of an integrated circuit socket; and
second ends of the plurality of the first trace pairs are coupled to first ends of the plurality of second trace pairs.

2. The PCB according to claim 1, wherein heights of the first trace pairs are greater than heights of the second trace pairs.

3. The PCB according to claim 1, wherein material in the break-out region of the PCB has a higher relative dielectric constant εᵣ than material in the main-route region of the PCB, thereby lowering the impedances of the first trace pairs.

4. The PCB according to claim 1, wherein the PCB is a multi-layer PCB having trace pairs in at least two layers of the PCB.

5. The PCB according to claim 4, wherein segments of the trace pairs in different layers of the PCB are connected together with vias from one layer to another layer.

6. The PCB according to claim 2, wherein connections from the first trace pairs to the second trace pairs step down in height.

7. The PCB according to claim 1, further comprising connecting the second ends of the plurality of second trace pairs to a connector mounted on the PCB for connecting to a matching cable connector.

8. The PCB according to claim 1, further comprising:
a second break-out region of the PCB having a plurality of third trace pairs, wherein the plurality of third trace pairs have impedances substantially the same as the impedances of the second trace pairs;
first ends of the plurality of the third trace pairs for coupling to connections of a second integrated circuit socket; and
second ends of the plurality of the third trace pairs are coupled to second ends of the plurality of second trace pairs.

9. The PCB according to claim 1, wherein the integrated circuit socket is configured to couple to a land grid array (LGA) integrated circuit package.

10. The PCB according to claim 1, wherein the integrated circuit socket is configured to couple to a pin grid array (PGA) integrated circuit package.

11. The PCB according to claim 1, wherein the integrated circuit socket is configured to couple to a ball grid array (BGA) integrated circuit package.

12. A method for impedance compensation of high-speed printed circuit board (PCB) differential pair channels, comprising:
providing a plurality of first trace pairs in a break-out region of a printed circuit board (PCB), wherein the plurality of first trace pairs have a first impedance;
providing a plurality of second trace pairs in a main-route region of the PCB, wherein the plurality of second trace pairs have substantially the first impedance;
coupling first ends of the plurality of the first trace pairs to connections of an integrated circuit socket; and
coupling second ends of the plurality of the first trace pairs to first ends of the plurality of second trace pairs.

13. The method according to claim 12, wherein heights of the first trace pairs are greater than heights of the second trace pairs.

14. The method according to claim 12, wherein PCB material in a break-out region of the PCB has a higher relative dielectric constant εᵣ than material in the main-route region of the PCB.

15. The method according to claim 12, further comprising:
mounting a connector on the PCB in the main-route region thereof; and
connecting the second ends of the plurality of second trace pairs to the connector.

16. A system in a package (SiP), comprising:
a substrate;
a plurality of first trace pairs in at least one break-out region of the substrate;
a plurality of second trace pairs in a main-route region of the substrate, wherein the plurality of first trace pairs have impedances substantially the same as the impedances of the second trace pairs;
at least one integrated circuit in the at least one break-out region of the substrate;
first ends of the plurality of the first trace pairs are coupled to connections of the at least one integrated circuit; and
second ends of the plurality of the first trace pairs are coupled to first ends of the plurality of second trace pairs.

17. The system in a package (SiP) according to claim 16, further comprising connecting second ends of the plurality of second trace pairs to through-silicon vias (TSV) in the substrate that are for coupling to external package connections of the SiP.

18. The system in a package (SiP) according to claim 16, wherein heights of the plurality of first trace pairs are greater than heights of the plurality of second trace pairs.

19. The system in a package (SiP) according to claim 16, wherein the substrate is at least one re-distribution layer (RDL).

20. The system in a package (SiP) according to claim 17, wherein the external package connections of the SiP are selected from the group consisting of land grid array (LGA), pin grid array (PGA) and ball grid array (BGA).
